(19) United States
(12) Patent Application Publication
(10) Pub. No.: US 2023/0305628 A1
(43) Pub. Date: Sep. 28, 2023

(54) BILATERAL VIBROTACTILE ACTUATOR

(71) Applicant: City University of Hong Kong, Kowloon (HK)

(72) Inventors: Xinge Yu, Kowloon (HK); Yiming Liu, Kowloon (HK); Wooyoung Park, Kowloon (HK)

(21) Appl. No.: 17/700,559

(22) Filed: Mar. 22, 2022

(51) Int. Cl. G06F 3/01; H01L 41/12; H01L 41/06

(52) U.S. Cl. CPC G06F 3/016; H01L 41/12; H01L 41/06

(57) ABSTRACT

A bilayer vibrotactile actuator adapted to provide a vibrational force. The bilayer vibrotactile actuator contains two metal coil layers separated from each other; and a magnet adapted to vibrate as a mass. Each of the two metal coil layers is adapted to be connected to an external power supply to generate an electromagnetic field, causing the magnet to vibrate. A wearable haptic feedback device containing the bilayer vibrotactile actuator is also disclosed. With two metal coil layers effecting on the magnet, the bilayer vibrotactile actuator can generate a more powerful overall magnetic field providing an enhanced haptic sensation to users.

### FIELD OF INVENTION

This invention relates to haptic actuators, and in particular to vibrotactile actuators based on the effect of electromagnetic field.

### BACKGROUND OF INVENTION

With the advancement of skin-integrated electronics, human skin sensational feedback including haptic, tactile, and heat has been highlighted in the field of metaverse (virtual reality (VR) and augmented reality (AR)), education, entertainment, and medical prosthesis due to its superior capability of reproducing sensed stimulus in reality. Especially, for metaverse that interacts with unsubstantial graphics, the application of a haptic feedback system is emphasized to provide a vivid sense of realism to users. By employing wearable devices installed with the haptic feedback system, VR users can be provided with immersive experiences such as vibration while they are touching or holding a graphical material in VR or AR. Therefore, currently, variations of haptic feedback devices adopted with different operating mechanisms applying an electromagnetic field, piezoelectric effect, and direct current (DC) motor were reported and commercialized. However, even though their performance as haptic feedback devices are proven and they are applied to commercialized products, most of them are faced with hurdles that cause considerable inconvenience to users for practical long-term applications.

To induce haptic sensation for human skin, some approaches have been tried, including electrostimulation and mechanical forces based vibratory actuation. Due to the huge differences in skin sensitivity to electrostimulation among people, a promising alternative option in generating haptic sensation to users relies on vibration-based actuators, which are soft and flexible actuator changing the displacement by piezoelectric effect and solid vibrotactile actuator generating vibrations by exploiting electromagnetic field or DC motor. The sensed stimulus is regenerated on users' epidermis by modifying the surface area of contact with pressure and in the form of rhythmic pulses respectively. Despite their verified working mechanisms and performance, the conventional haptic feedback devices are with critical flaws in the aspects of wearability and physical activities, including 1) a large quantity of operating electrical power input in a wide range from at least a few volts (V) to kilovolt (kV); 2) bulky size and massive weight resulted from their structural and working design; 3) the insufficient magnitude of response for practical applications; 4) weakness against mechanical impact. Due to the requirement of high working voltage, the adoption of a massive battery or other electrical power source is inevitable while the multiple devices are attached or worn by the users. Furthermore, vibrotactile actuators employing a DC motor as a source of vibration tend to lose functions as integrated into an encapsulated system with limited displacements. For actuators exploiting the piezoelectric effect for generating deformation of their contact surface area as a response, it is hard to expect noticeable sensational feedback in VR that mainly relies on vision compared to actuators using continuous vibrations. As users are more focused on the graphical interface of VR, it is unavoidable that the other senses except the visionary become dull. Therefore, a certain magnitude of response is required to notify users from interaction successfully. Lastly, although soft actuators exhibit remarkable flexibility and wearability that nurture their capability as promising wearable devices, they are with a tremendous defect, weakness against external mechanical impact. Because of the characteristics of VR and haptic feedback systems, the actuators are exposed to physical touch and impact repeatedly. However, the soft actuators with open-structure designs could easily lose functions due to unpredictable object entered or destructive external forces.

### SUMMARY OF INVENTION

Accordingly, the present invention, in one aspect, is a bilayer vibrotactile actuator adapted to provide a vibrational force. The bilayer vibrotactile actuator contains two metal coil layers separated from each other; and a magnet adapted to vibrate as a mass. Each of the two metal coil layers is adapted to be connected to an external power supply to generate an electromagnetic field, causing the magnet to vibrate.

In some embodiments, the magnet is located substantially between the two metal coil layers.

In some embodiments, the bilayer vibrotactile actuator further includes, between at least one of the metal coil layers and the magnet, a shielding layer preventing a direct contact of the magnet to the at least one of the metal coil layers.

In some embodiments, the shielding layer is a polyethylene terephthalate (PET) layer.

In some embodiments, the magnet has a disc shape, and is confined by a resin ring.

In some embodiments, there are two said shielding layers on two sides of the magnet, which together with a resin enclosure seals the magnet.

In some embodiments, the bilayer vibrotactile actuator further includes an adhesive layer via which one of the two metal coil layers is attached to an external substrate.

According to another aspect of the invention, there is provided a wearable haptic feedback device that includes a substrate, and a bilayer vibrotactile actuator which is attached to the substrate. The bilayer vibrotactile actuator contains two metal coil layers separated from each other; and a magnet adapted to vibrate as a mass. Each of the two metal coil layers is adapted to be connected to an external power supply to generate an electromagnetic field, causing the magnet to vibrate.

In some embodiments, the substrate is a flexible printed circuit board.

In some embodiments, the wearable haptic feedback device further contains an encapsulation that receives the substrate and the bilayer vibrotactile actuator therein.

In some embodiments, the encapsulation is formed by polydimethylsiloxane.

The bilayer vibrotactile actuators according to embodiments of the invention, which employ electromagnetic field, therefore present simplicity in both structure and operating mechanism, which are highly desired in practical long-term applications. Wearable and flexible VR devices based on such low-energy electromagnetic vibrotactile actuators are therefore possible with high wearability and stability for operating an enhanced haptic feedback system.

In particular, one can see that as bilateral vibrotactile actuators according to some embodiments of the invention adopt double metal coil layers at up and down sides of the magnet, so they can generate a wider range of tactile feedback compared to conventional actuators with a single metal coil layer. With this beneficial effect, advanced tactile feedback that is with an apparent and stronger sensation can be established. As a result, at metaverse including VR and AR that highly rely on vision, users are expected to experience a dynamic and vivid reality by using the bilayer actuator. In addition, it is expected to be integrated into functional prosthesis or electronic-skin (e-skin) for supporting amputees.

Additionally, in embodiments of the invention, the magnitude of the haptic feedback provided by the bilateral vibrotactile actuator can be manipulated according to sensed pressure at the metaverse by adjusting the value of power input and AC frequency to the metal coils. In addition, the bilateral vibrotactile actuator provides enhanced haptic feedback under a less electrical power consumption for reproducing tactile sensations at metaverse including VR and AR and further for amputees.

The actuator also exhibits its high stability and tolerance upon environmental, cyclic, and impact resistance tests. By exploiting such actuators, wearable VR equipment for the forearm, finger, and hand are fabricated with simple circuits to verify its superiority over conventional haptic actuators in the aspects of performance and application.

The foregoing summary is neither intended to define the invention of the application, which is measured by the claims, nor is it intended to be limiting as to the scope of the invention in any way.

### BRIEF DESCRIPTION OF FIGURES

The foregoing and further features of the present invention will be apparent from the following description of embodiments which are provided by way of example only in connection with the accompanying figures, of which:

FIG. 1 is a schematic illustration of the structure of a wearable haptic feedback device according to an embodiment of the invention.

FIG. 2 is an illustration of the structure of a bilateral vibrotactile actuator according to another embodiment of the invention.

FIGS. 3a-3c are schematic illustrations showing, in different states, the working principle of the actuator in FIG. 2.

FIG. 4 shows the electrical response of the actuators under the three working conditions shown in FIGS. 3a-3c.

FIG. 5 is a chart showing the shortest distance for discrete haptic feedback between the actuator at different body parts of a human.

FIG. 6 is an illustration showing an experimental setup in which an actuator is fixed to a flexible pressure sensor.

FIG. 7 shows the schematic diagram of the experimental setup in FIG. 6 for measuring the pressure induced by the actuator in FIG. 2.

FIG. 8 is a structural illustration of a flexible pressure sensor for evaluating the operational performance of the actuator in FIG. 2.

FIG. 9 shows simulated and measured operational response of the actuator in FIG. 2 with increasing voltage with fitted curve line.

FIGS. 10a-10c illustrate an operational performance of the actuator in FIG. 2 with a thickness of 1.9 mm, 2.3 mm and 2.7 mm respectively under increasing vibrational frequency.

FIGS. 11a-11c illustrate an operational performance of the actuator in FIG. 2 under different vibrational frequencies of 70, 60 and 50 Hz respectively, as a function of time.

FIG. 12 shows an operational response of the device of the actuator in FIG. 2 with increasing power input under 60 Hz of vibrational frequency, as a function of time.

FIG. 13 shows the cycling performance of the actuator in FIG. 2 under power input of 40.75 mA for 400,000 testing cycles.

FIG. 14 illustrates an operational performance of the actuator in FIG. 2 with different ring diameters of 3.5, 6.5, and 11 mm under increasing electrical power input.

FIG. 15 illustrates an operational performance of the actuator in FIG. 2 before and after over 100 cycles of impact resistance test with optical image of the experimental setup for impact resistance testing.

FIG. 16a shows a FEA model of the actuator in FIG. 2 under uniformly distributed force with pressure of 5.53 MPa.

FIG. 16b shows the stress distribution of PET component in the actuator in FIG. 2.

FIG. 16c shows the stress distribution of Cu coil layer in the actuator in FIG. 2.

FIG. 16d shows the stress distribution of epoxy ring in the actuator in FIG. 2.

FIG. 17 shows the maximum temperature generated by the actuator in FIG. 2 under different environments.

FIG. 18 shows a thermal response of the actuator in FIG. 2 in the air as a function of time.

FIG. 19a is a thermal image of the actuator in FIG. 2 as it is placed in the air.

FIG. 19b is a FEA image of the actuator in FIG. 2 as it is placed in the air.

FIG. 19c is a thermal image of the actuator in FIG. 2 as it is placed in water.

FIG. 19d is a FEA image of the actuator in FIG. 2 as it is placed in water.

FIG. 19e is a thermal image of the actuator in FIG. 2 as it is placed on sand

FIG. 19f is a FEA image of the actuator in FIG. 2 as it is placed on sand.

FIG. 20 shows a temperature change of the actuator in FIG. 2 in the air as a function of current input.

FIG. 21 shows a block diagram of a wearable BV-actuator VR device system according to another embodiment of the invention.

FIG. 22a shows programmable actuating patterns of a VR equipment with 2×2 actuator arrays according to another embodiment of the invention.

FIG. 22b illustrates grid views of the accuracy of testing results for the VR equipment in FIG. 22a.

FIG. 23a shows programmable actuating patterns of a VR equipment with 3×3 actuator arrays according to another embodiment of the invention.

FIG. 23b illustrates grid views of the accuracy of testing results for the VR equipment in FIG. 23a.

FIG. 24a shows a grabbing arm in a VR interface associated with a VR equipment according to another embodiment of the invention.

FIG. 24b shows a photo of the VR equipment in FIG. 24a.

FIG. 24c shows haptic feedback of the VR equipment in FIG. 24a.

FIG. 25a shows a punching arm in a VR interface associated with a VR equipment according to another embodiment of the invention.

FIG. 25b shows a photo of the VR equipment in FIG. 25a.

FIG. 25c shows haptic feedback of the VR equipment in FIG. 25a.

FIG. 26a shows poking actuators in a VR interface associated with a VR equipment according to another embodiment of the invention.

FIG. 26b shows a photo of the VR equipment in FIG. 26a.

FIG. 26c shows haptic feedback of the VR equipment in FIG. 26a.

FIGS. 27a-27b illustrate respectively grabbing a ball in a VR interface and the graphical distributions of haptic feedback at a VR equipment, according to another embodiment of the invention.

FIGS. 28a-28b illustrate respectively holding a cup in a VR interface and the graphical distributions of haptic feedback at a VR equipment, according to another embodiment of the invention.

FIGS. 29a-29b illustrate respectively placing a cube on a hand in a VR interface and the graphical distributions of haptic feedback at a VR equipment, according to another embodiment of the invention.

In the accompanying figures, like numerals indicate like parts throughout the several embodiments described herein.

### DETAILED DESCRIPTION

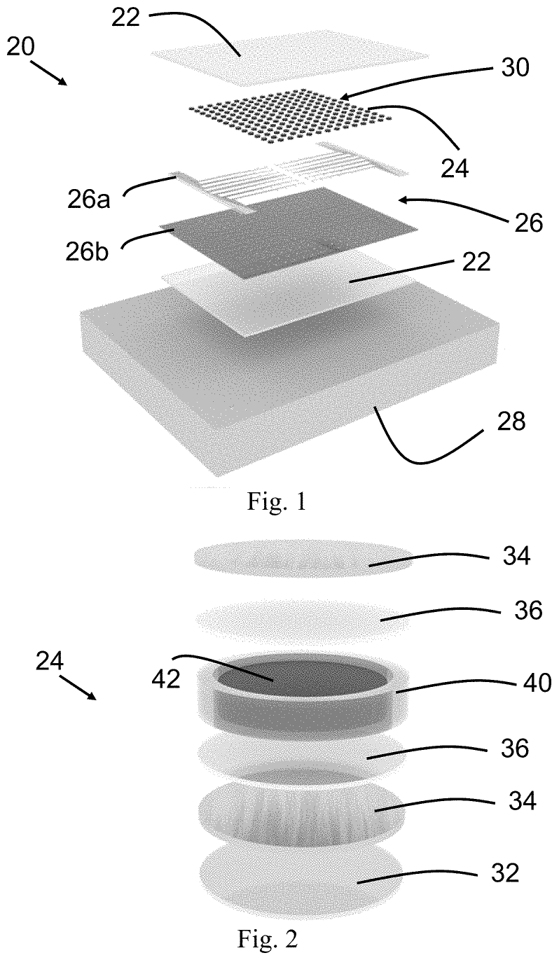

Referring now to FIG. 1, a wearable haptic feedback device 20 according to a first embodiment of the invention is illustrated. The wearable haptic feedback device 20 is suitable to be used in a VR system (not shown) in which a user wearing VR equipment including a headset (not shown) and the wearable haptic feedback device 20 interacts with virtual characters or objects, for example the user could fight with a boxer in gaming graphics. As shown by the schematic diagram in FIG. 1, the wearable haptic feedback device 20 includes a flexible printed circuit board (FPCB) layer 26 that consists of a flexible substrate 26b and conductive copper (Cu) circuit patterns 26a on top of the flexible substrate 26b. The FPCB layer 26 can be seen to have a rectangle shape, and is mounted with an actuator array 30 which consists of a number of bilateral vibrotactile actuators 24. All the actuators 24 as shown in FIG. 1 are evenly distributed to be in a rectangle formation on a top side of the FPCB layer 26. The FPCB layer 26 and the actuator array 30 are then encapsulated by two polydimethylsiloxane (PDMS) layers 22 at the top side and the bottom side thereof. The resultant feedback device 20 with the encapsulation is then suitable for directly contacting a human skin 28 and provide haptic feedback to the skin 28.

For the FPCB layer 26, the circuit patterns 26a were embedded in a highly bendable polyimide (PI) sheet shielding the circuit patterns 26a from potential damage and short-circuiting, while the actuator array 30 of the actuators 24 is directly soldered on the FPCB layer 26. Therefore, under a controlled electrical power input, the actuators 24 mounted on the FPCB layer 26 are adapted to respond according to a current delivered through the circuit patterns 26a. Subsequently, the two PDMS layers 22 encapsulate the wearable haptic feedback device 20 at the top and bottom to further protect its components from damages, and to provide skin attachment. The two PDMS layers 22 are flexible. As a result, the wearable haptic feedback device 20 as a whole is immensely bendable and twistable, and is attached to human epidermis tightly without failure even with the user's physical activities during operation.

Turning to FIG. 2, the structural design of an exemplary actuator 24 in the actuator array 30 is illustrated. In this embodiment, all actuators 24 in the actuator array 30 are the same. It should be noted that although the exemplary actuator 24 has the structure shown in FIG. 2, in other embodiments the actuators in an actuator array may have different structures from each other, and/or have structures different from what is shown in FIG. 2. The actuator 24 shown in FIG. 2 has six layers which are piled up layer by layer to act as a single actuator device. All six layers have a substantially round shape in a top view of the actuator 24. At the bottommost side, an adhesive material layer 32 is placed as a substrate of the actuator 24, and the adhesive material layer 32 can be adhered at its bottom side to external objects such as the flexible substrate 26b of the FPCB layer 26 as mentioned above. On the top side of the adhesive material layer 32 there is attached a Cu coil layer 34, and opposite to this Cu coil layer 34 there is another Cu coil layer 34 located at the top end of the actuator 24. Between the two Cu coil layers 34 there are sandwiched, in sequence, a polyethylene terephthalate (PET) layer 36, a magnet 42 received within an epoxy ring 40, and another PET layer 36. In other words, the epoxy ring 40 and the magnet 42 are located at the center of the six-layer structure of the actuator 24. The two CU coil layers 34 are a type of metal coil layers, and are separated from each other. The two CU coil layers 34 are adapted to be powered to generate electromagnetic fields when connected to an external power supply (e.g., the FPCB layer 26 as mentioned above). Because of the electromagnetic field the magnet 42 between the two CU coil layers 34 is then adapted to vibrate, as will be described in more details later. The epoxy ring 40 as a type of resin enclosure seals the magnet 42 together with the two PET layers 36 to protect the Cu coil layers 34 at the top and bottom from direct collision and damage by the magnet 42 when it is vibrating, and in the meantime to keep the whole actuator 24 waterproof. The structure delimited by the epoxy ring 40 and the two PET layers 36 has a cylindrical shape to receive therein the magnet 42, which has a disc shape.

Having described the structures of the actuator 24 and the wearable haptic feedback device 20 above, the working principle of the actuator 24 and the wearable haptic feedback device 20 will now be described. As mentioned above, in each actuator 24 the two Cu coil layers 34 generate coupled magnetic fields when an electrical power source is applied, and in the wearable haptic feedback device 20 the electric power is transmitted to actuators 24 via the FPCB layer 26. The magnet 42 at the center of the actuator 24 performs as a vibrator because of the magnetic fields induced by the Cu coil layers 34. The two PET layers 36 between the Cu coil layers 34 and the magnet 42 serve as a shield protecting the Cu coil layers 34 from vibration of the magnet 42 and also as sealing layers for waterproof purposes, while the epoxy ring 40 performs as a supporting material confining the magnet 42. Because of the two separate magnetic fields generated by the Cu coil layers 34, vibration of the magnet 42 with a powerful force can be produced during operation of the bilateral vibrotactile actuator 24. On the other hand, as the actuator 24 contains double Cu coil layers 34 at top and bottom ends, it would generate a wider range of tactile feedback compared to conventional actuators including only a single Cu coil layer. Through this advantage, advanced tactile feedback provided by the wearable haptic feedback device 20 that contains the actuators 24 with an apparent and stronger sensation can be established. As a result, at metaverse including VR and AR that highly rely on vision, users are expected to experience a dynamic and vivid reality by using the wearable haptic feedback device 20. In addition, it is expected that the wearable haptic feedback device 20 can be integrated into functional prosthesis or electronic-skin (e-skin) for supporting amputees.

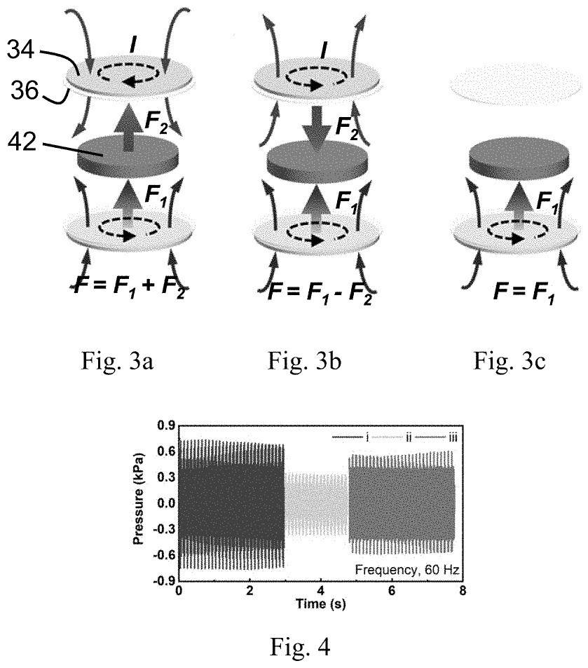

FIGS. 3a-3c illustrate the working mechanism of the actuator 24 under alternating current (AC) electrical power input. Following the right-hand rule of the magnetic field, while AC power is applied to the Cu coil layers 34 of the actuator 24, the vibration source which is the magnet 42, as it is trapped between two composite layers each consisting of a Cu coil layer 34 and a PET layer 36, is affected by the magnetic fields generated by the Cu coil layers 34. The Cu coil layer 34 with electrical power produces a static magnetic field around itself, which forms the shape of a bar magnet giving distinct North and South poles. The magnet 42 between the top and bottom Cu coil layers 34 is subject to forces in the same direction when the current flows in opposite directions in the two Cu coil layers 34 because of like poles repelling and unlike poles attracting each other (as shown in FIG. 3a). Otherwise, the magnet 42 is subject to opposite forces when the current flows of the Cu coil layers 34 are in the same directions (as shown in FIG. 3b). With the presence of two separate magnetic fields generated by the two Cu coil layers 34, compared to conventional single-Cu-coil vibrotactile actuators, a stronger vibrational force can be achieved during operation (as shown in FIG. 3c).

Next, the descriptions go to discussion of experiments conducted to investigate the optimal structural dimensions and vibration frequency of the actuator 24 for generating the largest range of haptic feedback from the actuator 24. The operational performance of the actuator 24 had been optimized by conducting experiments with controlled variables such as thickness of the epoxy ring 40 affecting the overall size of the device, and the vibration frequency of the actuator 24. FIG. 4 illustrates the pressure generated by the actuators at the three conditions shown in FIGS. 3a-3c with a constant AC input of 63.75 mA and 60 Hz, which further proves that the actuator 24 could yield the most intense vibration under the condition shown in FIG. 3a. As the actuator 24 generates high-pressure force and low-pressure force repeatedly, clear vibrations can be delivered to a user through rhythmical pressure difference. It should be noted that the power of the haptic feedback that is the magnitude of vibration force induced by the actuator 24 can also be manipulated by adjusting the amount of electrical power input. In particular, the power of the feedback is proportional to the input current. Therefore, by applying different electrical power to the actuator based on the pressure sensed, obviously distinguished levels (magnitudes) of haptic feedback can be delivered to a user.

In addition, to achieve operation diversity, prototypes of actuators 24 are fabricated with three different diameters 3.5 mm, 6.5 mm, and 11 mm, and separately with three different thicknesses 2.8 mm, 3.2 mm, and 3.6 mm. The thickness here refers to the thickness of the entire actuator 24 as shown in FIG. 2. It is found that depending on the sensational sensitivity and surface area of target skin, different arrays and sizes of the actuators can be utilized to maximize the quality of feedback. In one prototype, a single unit of the actuator 24 has a total size of 11 mm×2.8 mm (diameter×thickness) in the top and side view respectively.

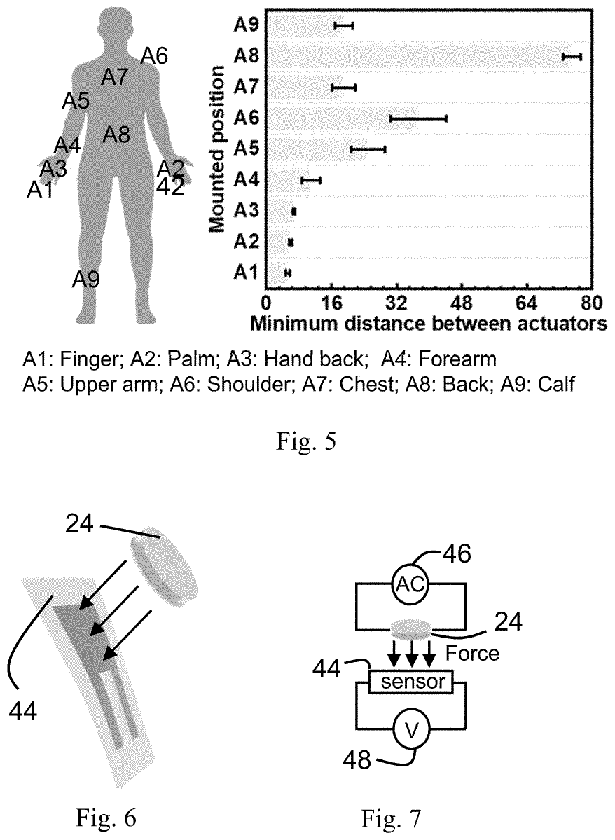

Thereafter, the minimum distances between two separate actuators 24 in the wearable haptic feedback device 20 for discrete haptic feedback were measured at different target body regions (finger, palm, hand back, forearm, upper arm, shoulder, chest, back, and calf), to determine designs of the actuator array including the arrangement of the actuators 24 in the wearable haptic feedback device 20 and gaps among them. In addition, the minimum distance of two adjacent actuators 24 for maintaining vibration function under four conditions is measured, which can be made a useful guide in designing the bilateral vibrotactile actuator's practical applications in the future. Consequently, FIG. 5 shows in the various mounted positions on the human body, the measured minimum distance between actuators which are 5.33 mm, 6 mm, 6.83 mm, 11 mm, 25 mm, 37.33 mm, 19 mm, 75 mm, and 19 mm, respectively. According to the measurement, it clearly demonstrated that the finger is with the highest sensational sensitivity while the back owns the lowest. As a result, a relatively more compact design could be applied for fingers compared to the other target areas on the human body. Based on the data recorded in FIG. 5, various wearable haptic feedback devices (which have different form factors as compared to the wearable haptic feedback device 20 in FIG. 2) targeting finger, palm, and forearm of human body can be designed and fabricated. Especially for the finger, different sizes (diameters of 3.5 and 6.5 mm) and arrays (3×3 and 2×2) of the actuators were adopted while 11 mm actuators are exploited for palm and forearm. In virtue of the remarkable characteristics of the constituent materials, FPCB and PDMS, the wearable haptic feedback devices could be tightly mounted on targets with their high bendability and robust attachment.

Turning now to FIGS. 6-7, in which an experimental setting for recording the pressure force produced by the actuator 24 are shown. For the experiments, the actuator 24 is directly placed on a flexible pressure sensor 44 to record the numerical strength of pressure generated by the vibrations produced by the actuator 24 during operation. As shown in FIG. 7, the actuator 24 on the sensor 44 is operated by electric power from an AC power source 46 that is provided by a waveform generator (not shown), while the pressure measured by the sensor 44 is recorded and displayed on a computer 48 that is connected to the sensor 44.

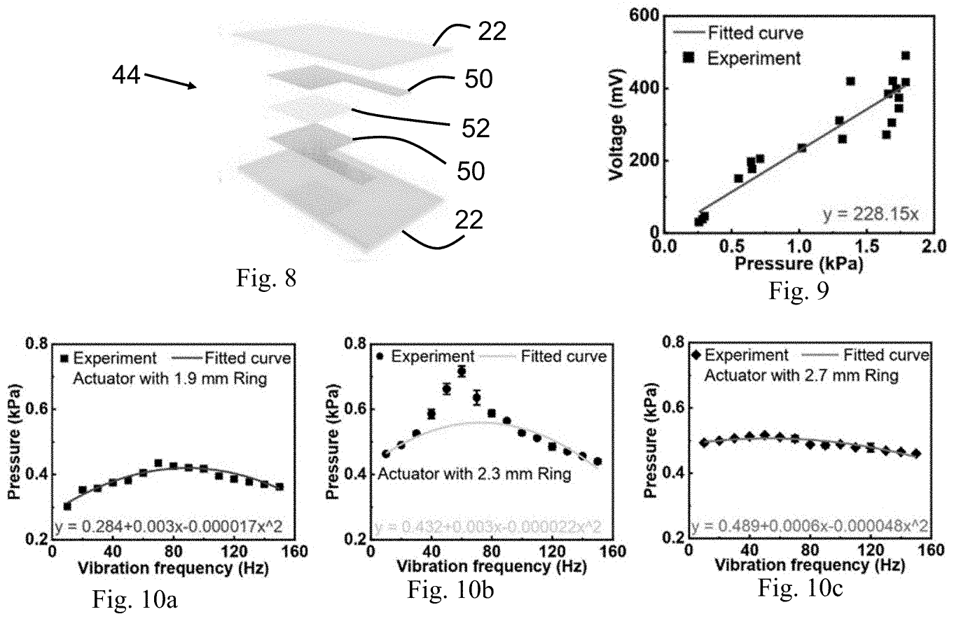

The flexible pressure sensor 44 has a structure shown in FIG. 8, and the sensor 44 as a piezoelectric pressure sensor includes two thin platinum (Pt) layers 50 each with a size of 1 cm×1 cm×50 nm (length×width×thickness). The two Pt layers 50 sandwich a barium-calcium zirconate titanate (BCZT) layer 52 that has a size of 1 cm×1 cm×400 nm (length×width×thickness). Like in the actuator 24, there are two PDMS layers 22 in the sensor 44. The PDMS layers 22 encapsulate the Pt layers 50 and the BCZT layer 52 for protecting the same, as well as for producing different values of output voltages upon pressures applied on the PDMS layers 22 due to piezoelectric effect. The two PDMS layers 22 have different thicknesses (50 μm for the top PDMS layer 22 and 1 mm for the bottom PDMS layer 22).

First, to reveal the relationship between the input voltage of the actuator 24 and the pressure produced by the vibration, the vibrational force was recorded while increasing the input electrical power from 0 to 500 mV, which is shown in FIG. 9. Accordingly, it is proved by the fitted curve drawn in FIG. 9, that the input voltage is proportional to the pressure produced by the vibration. As a result, it clearly exhibits that the magnitude of the haptic feedback can be manipulated by adjusting the value of input electrical power. Additionally, to figure out the optimal thickness of the actuator 24, the performance tests had been conducted by exploiting different thicknesses of the epoxy ring 40 that are 1.9 mm, 2.3 mm, and 2.7 mm while increasing the vibration frequency of the magnet 40 (from 10 to 150 Hz) under fixed electrical power input. Referring to FIGS. 10a-10c, the actuator with the ring thickness of 2.3 mm generated the most powerful feedback (0.72 kPa at 60 Hz, see FIG. 10b) while the device with the thickness of 2.7 mm delivered (0.52 kPa at 50 Hz, see FIG. 10c) a stronger force than that of 1.9 mm (0.43 kPa at 70 Hz). Therefore, it is verified that the 2.3 mm of the epoxy ring 40 provides the largest range of tactile sensation to a user. Additionally, according to FIGS. 10a-10c, the operational stability under growing frequency was demonstrated by the R-square values of the fitted curves for each actuator (0.94, 0.98, and 0.96 respectively).

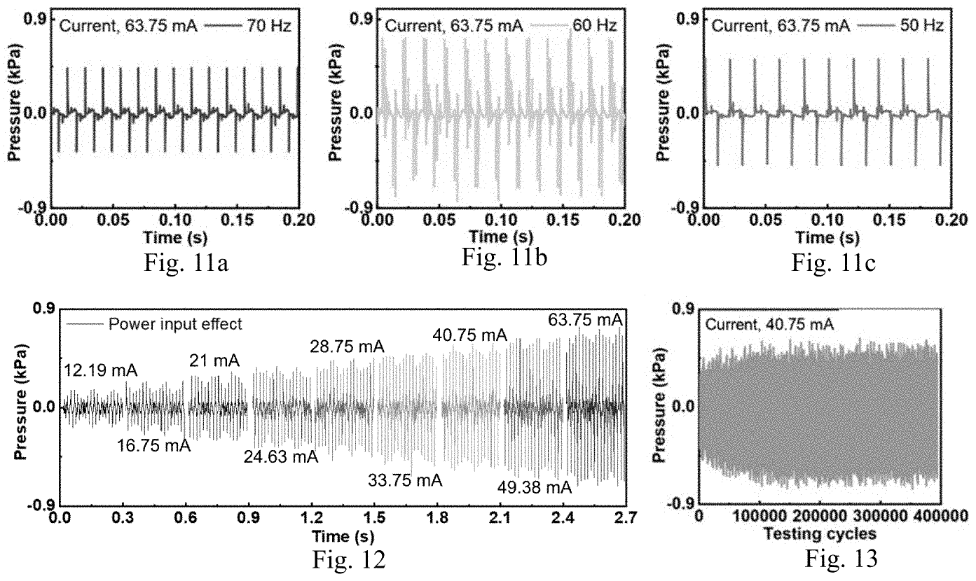

Thereafter, the optimal vibration frequency of the actuator 24 was investigated by using the dimension that showed the best performance (i.e., with the 2.3 mm thick epoxy ring, with which the overall thickness of the actuator 24 being 3.2 mm). Under a constant input current of 63.75 mA, the actuator 24 was tested with the frequency of 50, 60, and 70 Hz as shown in FIGS. 11a-11c respectively. Among them, the actuator 24 applied with the vibration frequency of 60 Hz produced apparently the largest vibrational force compared to the others. As a result, via this test, 60 Hz was selected as the optimum vibration frequency for the actuator 24. Consequently, to measure the values of electrical power input required for generating consciously distinguished vibrations, 12.19, 16.75, 21, 24.63, 28.75, 33.75, 40.75, 49.38, and 63.85 mA of current are applied to the actuator with the time interval of 0.3 s as shown in FIG. 12. As shown in FIG. 12, as the quantity of input current elevates, higher levels of pressure had been measured obviously (0.17 kPa, 0.24 kPa, 0.30 kPa, 0.36 kPa, 0.45 kPa, 0.49 kPa, 0.59 kPa, 0.63 kPa, and 0.72 kPa, respectively). It is proved that the magnitude of haptic feedback can be regulated by adjusting the power input according to the sensed stimulus. Thereafter, the relationship between operating performance and diameter of the actuator was demonstrated by applying increasing AC input to the actuators with diameters of 3.5, 6.5, and 11 mm at a constant thickness of 3.2 mm. As a result, throughout the experiment, per every time interval, there was an obvious increment of the magnitude of the pressure. Therefore, it is identified that at least nine stages of feedback level can be adopted based on the magnitude of the stimulus. According to FIG. 14, it was revealed that the actuator 24 with the larger diameter can generate noticeably a wider range and higher value of haptic feedback while more steep increases were observed simultaneously. Furthermore, a larger quantity of power input can be managed by bigger actuators. As a result, the larger diameter BV-actuators can be applied on target body parts with less sensational sensitivity. Furthermore, through the power input effect, it is verified that the magnitude of the vibrational force generated by the actuator can be manipulated by regulating the electrical power input, its dimensions and AC frequency.

At last, the high stability and repeatability of the actuator had been proved via a cyclic experiment under constant variables (with 2.3 mm thick epoxy ring, a frequency of 60 Hz, and a constant current of 40.75 mA) for a prototype of the actuator 24. In accordance with the measurement results shown in FIG. 13, for 400,000 times of iteration, the actuator 24 generated fairly stable results without failure. As a result, through these performance tests, the optimal size and vibration frequency of the actuator 24 for the largest haptic feedback range was measured as 2.3 mm thick epoxy ring, and 60 Hz respectively. In addition, the working mechanism, stability, and repeatability were revealed further.

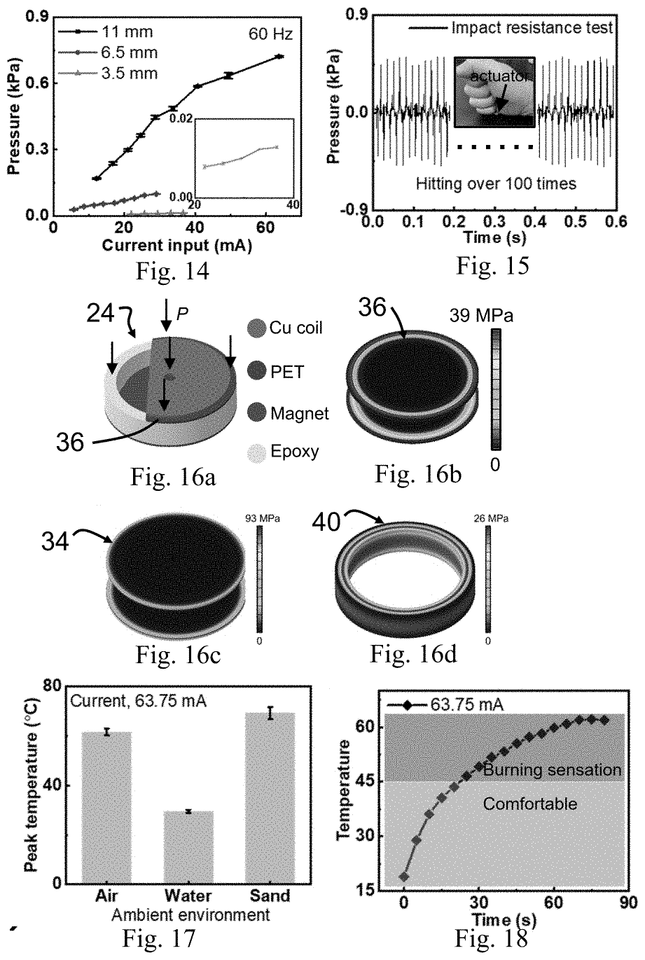

Next, the impact resistance capacity and the thermal characteristic of the actuator 24 is evaluated to verify its stability and operation guarantee under various environmental conditions. As shown in FIG. 16a, uniformly distributed force with pressure of 5.53 MPa was applied on the top surface of the actuator 24, and from the FEA (Finite Element Analysis) image in FIG. 16 one can see that the PET layer 36 is the first part of the whole structure of the actuator 24 to reach its compressive yield strength (40 MPa) as shown in FIG. 16b. In addition, the stress distribution of other parts of actuator 24 including Cu coil layer 34 and the epoxy ring 40 are calculated in FIG. 16c and FIG. 16d respectively. Subsequently, an impact resistance test was performed for checking its tolerance against mechanical impact. In the experimental setting of the test that a tester wears a nitrile glove to continuously smash the actuator 24 for over 100 times (see FIG. 15). Before and after the resistance experiment, the actuator 24 can generate a constant vibrational force without obvious decay, demonstrating its excellent stability.

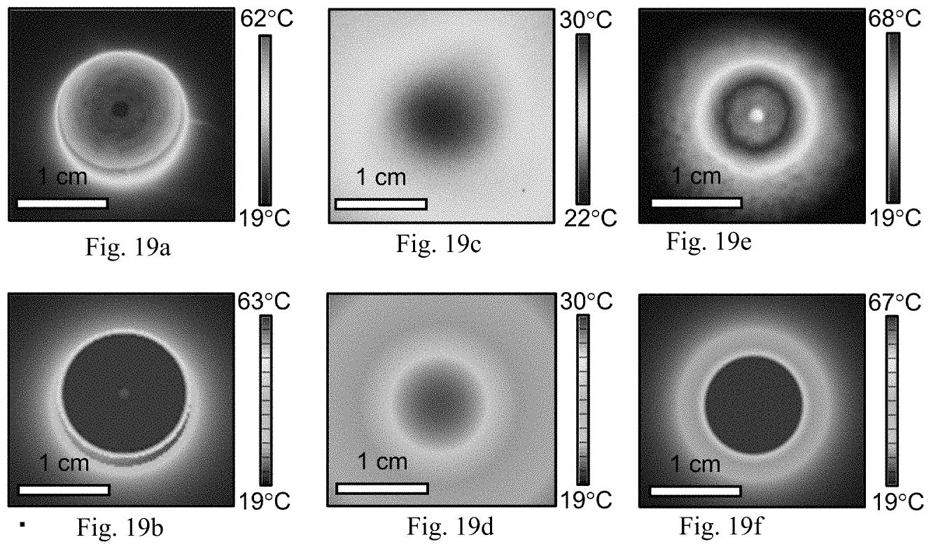

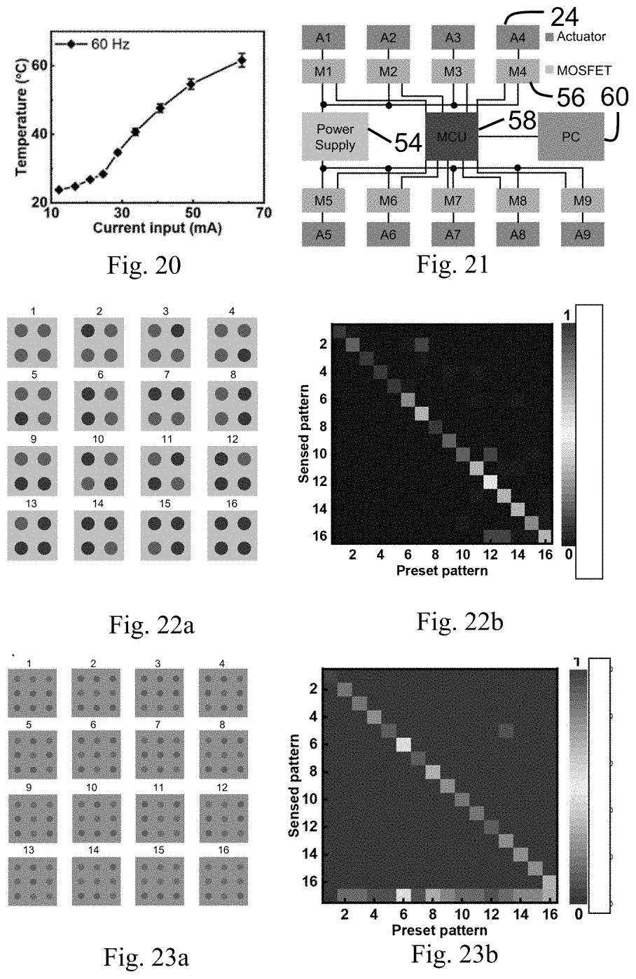

Thereafter, the actuator 24 is placed and operated within air, water, and directly on sand respectively as it was placed on a PDMS substrate (PDMS:crosslink=30:1) with a size of 7.5 cm×7.5 cm×3 mm (length×width×thickness) for mimicking human epidermis to validate the workability of the actuator under different environments. At the same time, the thermal status and heat dissipation of the functioning actuator 24 under the condition producing the maximum vibration force (63.75 mA of current input and vibration frequency of 60 Hz) was captured accordingly by a thermal imaging camera to quantify the maximum temperature resulted in FIGS. 19a, 19c, 19e (61.6° C., 29.6° C., and 69.2° C. respectively), which is further proved by the thermal theoretical results (FIG. 19b, 19d, 19f). In FIG. 17, the maximum thermal dissipation of the actuator 24 under different ambient environments is compared, where the peak temperature (69.2° C.) generated by the actuator 24 was largest on the sand and it was slightly lower in air while it showed the lowest temperature in water. As the threshold temperature for an instant skin burn is approximately 60° C., the current input and time required for the actuator 24 to reach the maximum temperature in air, 61.6° C., were measured under fixed variables (60 Hz of vibration frequency and 63.75 mA of input current respectively). Referring to FIG. 20, under 60 Hz, the actuator 24 produced the peak temperature when 63.75 mA of electrical power was applied. Following, under 63.75 mA, more than 1 min was taken for generating the peak temperature (see FIG. 18). Furthermore, approximately 25 seconds were taken for reaching 45° C. which is the thermal point where human commences to feel a burning sensation. As a result, the minimum duration for reaching the maximum thermal energy level was revealed as more than 1 minute that is a fairly long-time in the aspect of haptic feedback initiated by a touch. Finally, the actuator 24 was operated under high and low temperatures in air (60 and 1.5° C.), in water, and in sand respectively to test its thermal tolerance and to firmly confirm the working environments of the actuator 24. As a result, it was proved that the actuator 24 can generate vibrations without any degradation under ambient conditions. Consequently, via experiments, working environmental variations (in air, water, and on sand) and its high stability and tolerance against mechanical impact were verified. In addition, the potential risk of skin burn resulting from the actuator 24 could be investigated that strongly recommends users not to be exposed to the maximum vibration force of more than 1 min.

After the evaluation of the bilateral vibrotactile actuator, a wearable bilateral vibrotactile actuator VR equipment installed with a number of actuators 24 had been tested for examining the pattern accuracy of the VR equipment. The VR equipment was directly connected to a control panel (not shown) for programming and manipulating the pattern for operation. In addition, for experiments, direct current (DC) power was utilized by creating pulse width modulation (PWM) signals for inducing the electromagnetic field. To connect the VR equipment and the control panel tightly and safely, a flexible printed circuit (FPC) connector (not shown) was exploited and therefore, unlike wires, exceptional mechanical and electrical stability could be achieved. FIG. 21 then shows the structure of a wearable bilateral vibrotactile actuator VR device system includes the wearable bilateral vibrotactile actuator VR equipment mentioned above, a power supply 54, and a MCU (microcontroller unit) 58 and a personal computer (PC) 60. The wearable bilateral vibrotactile actuator VR equipment device contains multiple actuators 24 each of which being connected, via a respective MOSFET 56, to the power supply 54 and the MCU 56. The power supply 54 and the MCU 56 are configured on the control panel, so they are connected to the MOSFETs 56 and the actuators 24 via the FPV connector. The MCU 56 is also carried on the control panel, and the MCU 56 connected to the PC 60 via other communication means like serial cables.

It should be noted that although the power supply 54 is shown in FIG. 21 as a separate component from the PC 60, in fact the power supply 54 is provided by the PC 60. As such, in the experimental setup, the PC 60 is connected to the MCU 58 for performing as the power source 54 as well as for programming the actuators 24 while each general-purpose input/output (GPIO) of the MCU 58 transmits a digital signal to the corresponding MOSFET 56 of an actuator 24 for switching. Therefore, when the MOSFETs 56 are turned on by the MCU 58, an external DC power can flow to the corresponding actuators 24 for generating vibrations. As a result, by regulating GPIOs through programming the MCU 58, different actuating patterns could be accomplished.

For the accuracy tests, two wearable BV-actuator VR devices with different numbers and sizes of actuators and configurations (2×2 with 6.5 mm-diameter actuator and 3×3 with 3.5 mm-diameter actuator arrays) targeting a fingertip are built. The wearable BV-actuator VR devices with the 2×2 actuator array is shown in FIG. 22a, while the wearable BV-actuator VR devices with the 3×3 actuator array is shown in FIG. 23a. The fingertip was chosen as the target human body portion because it has the highest sensational sensitivity as mentioned before, so the wearable BV-actuator VR devices can be fabricated in the most compact design. For each of the two wearable BV-actuator VR devices, a total of 16 distinct patterns were prepared as shown in FIGS. 22a and 23a, and a group of 10 testers wore the devices for 10 sets of blind tests. Then, to enhance the reliability of the experiment results, the testers chose the patterns in the list they recognized from the vibrations while the preset patterns were generated randomly. FIG. 22b and FIG. 23b illustrate the testing results indicating the accuracy of pattern recognition of the wearable BV-actuator VR device with the 2×2 actuator array device, and the wearable BV-actuator VR device with the 3×3 actuator array device respectively. For the 3×3 actuator array, 17 sensed patterns including offset are displayed due to the complexity of patterns resulting from the increasing number of actuators while the 2×2 device exhibits 16 sensed patterns matching with the preset patterns. According to the grid charts in FIGS. 22b and 23b, the overall patterns recognition rate of two arrays (2×2 actuators array and 3×3 actuators array) could reach up to 83.75% and 80.77%, respectively. This phenomenon is on account of the high-density design of the devices and the similarities among the preset patterns. Furthermore, the devices were not customized to the testers' finger proportions, and this led to unstable adhesion between the epidermis and the device. Through the pattern recognition tests for the VR equipment, the working mechanism of the devices and the pattern accuracy of haptic feedback were demonstrated. According to the results, the requirement of customized devices for providing enhanced quality of feedback is emerged.

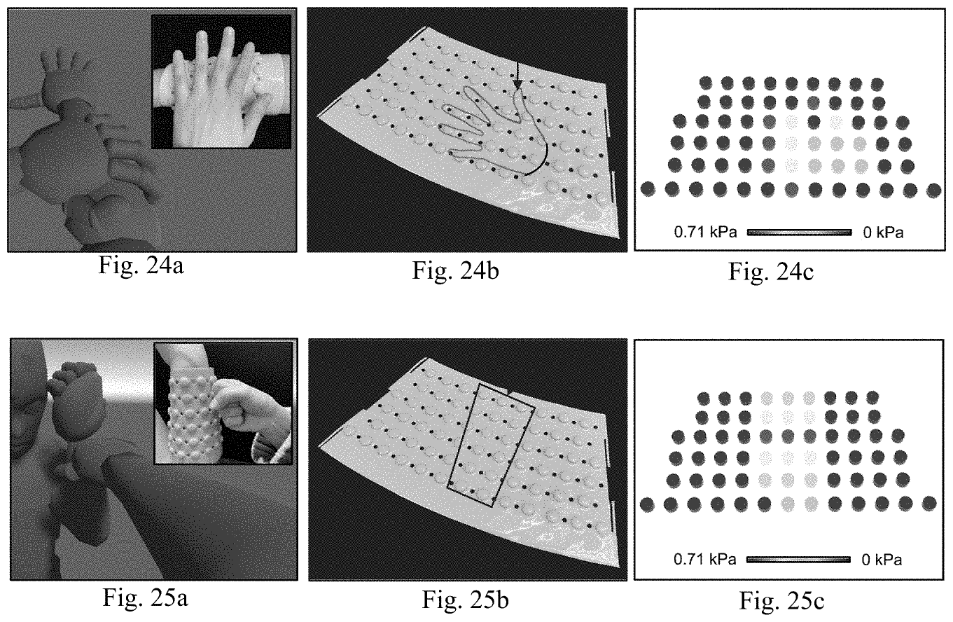

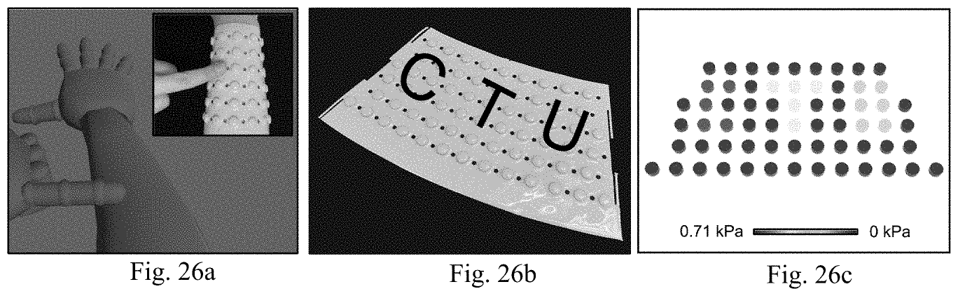

Following, the wearable BV-actuator VR devices for the forearm and hand (including palm and fingers) were managed under a VR environment (Unity game engine) for inspecting its performance. While a user interacted with the graphical interface of the VR system, the corresponding actuators in touch or under pressure vibrated according to the applied force at metaverse by applying different quantity of electrical power. Therefore, a high-resolution and detailed haptic feedback system can be achieved by manipulating each actuator separately. For the study, three different actions were tested for each device separately. First, for the forearm, a user grabbed his own forearm (FIG. 24a), the forearm was being punched (FIG. 25a), and the user poked his forearm in the pattern of a word, “CTU” (FIG. 26a) in the VR environment while the haptic feedback areas for the situations were recorded respectively (FIGS. 24b, 25b, and 26b). Subsequently, the vibrational force generated by each actuator were represented by different grayscales (which correspond to 0.72 kPa, 0.59 kPa, 0.45 kPa, 0.30 kPa, and 0 kPa applying 63.75 mA, 40.75 mA, 28.75 mA, 16.75 mA, and 0 mA of AC power, respectively). For grabbing, it can be clearly observed that the actuators for the fingertips generated the most powerful vibrations while at the bottom of the palm was with the lowest magnitude (FIG. 24c). Following, for punching, the middle parts of the device detected and released the strongest haptic feedback (FIG. 25c). Then, for the pattern, “CTU”, each character was generated by three different magnitudes of haptic feedback as the tester applied force discriminately in purpose for apparently distinguishing the letters (FIG. 26c).

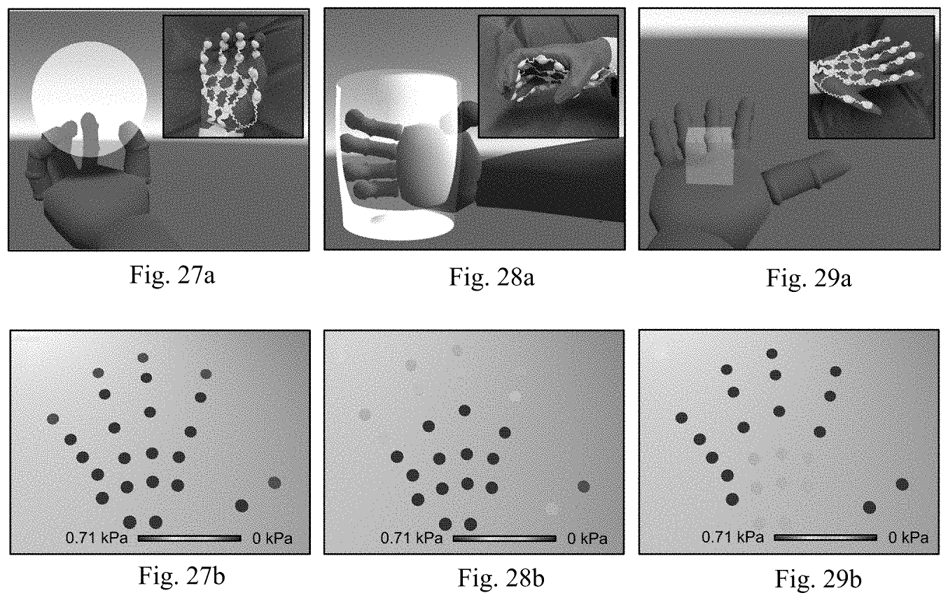

Next, a user grabbed a ball (FIG. 27a) and a cup (FIG. 28a), and a cube was placed on a hand (FIG. 29a) in the VR game engine respectively for testing the device targeting a hand. Like the aforementioned forearm device, the pressure generated by each BV-actuator was displayed in grayscales through the graphical distributions respectively. For the ball, as the ball was only held tightly by fingertips, the actuators located on the fingertips were vibrated hardly while the others were turned off (FIG. 27b). For holding a cup, every two joints of the fingers detected pressure and operated accordingly (FIG. 28b). Furthermore, as the cube was placed on the palm excluding fingers, only the actuators on the palm were operated according to the weight of the cube (FIG. 29b). Consequently, these results highly match compared to the real human motion behaviors including grabbing, being punched, poking, holding, and lifting in the aspect of force distributions of the physical motions. As a result, after the VR test, the operational performance of the wearable BV-actuator VR devices in VR environments was proved as the devices successfully reproduced the patterns resulted from VR interaction while the magnitude of pressure applied for each subregion was actualized simultaneously.

The exemplary embodiments are thus fully described. Although the description referred to particular embodiments, it will be clear to one skilled in the art that the invention may be practiced with variation of these specific details. Hence this invention should not be construed as limited to the embodiments set forth herein.

While the embodiments have been illustrated and described in detail in the drawings and foregoing description, the same is to be considered as illustrative and not restrictive in character, it being understood that only exemplary embodiments have been shown and described and do not limit the scope of the invention in any manner. It can be appreciated that any of the features described herein may be used with any embodiment. The illustrative embodiments are not exclusive of each other or of other embodiments not recited herein. Accordingly, the invention also provides embodiments that comprise combinations of one or more of the illustrative embodiments described above. Modifications and variations of the invention as herein set forth can be made without departing from the spirit and scope thereof, and, therefore, only such limitations should be imposed as are indicated by the appended claims.

1. A bilayer vibrotactile actuator adapted to provide a vibrational force, comprising:
a) two metal coil layers separated from each other; and
b) a magnet adapted to vibrate as a mass;
wherein each of the two metal coil layers is adapted to be connected to an external power supply to generate an electromagnetic field, causing the magnet to vibrate in directions substantially perpendicular to the two metal coil layers as the magnet is subjected to magnetic forces caused by both of the two metal coil layers.

2. The bilayer vibrotactile actuator according to claim 1, wherein the magnet is located substantially between the two metal coil layers.

3. The bilayer vibrotactile actuator according to claim 2, further comprises, between at least one of the metal coil layers and the magnet, a shielding layer preventing a direct contact of the magnet to the at least one of the metal coil layers.

4. The bilayer vibrotactile actuator according to claim 3, wherein the shielding layer is a polyethylene terephthalate layer.

5. The bilayer vibrotactile actuator according to claim 1, wherein the magnet has a disc shape, and is confined by a resin ring.

6. The bilayer vibrotactile actuator according to claim 3, wherein there are two said shielding layers on two sides of the magnet, which together with a resin enclosure seals the magnet.

7. The bilayer vibrotactile actuator according to claim 1, further comprising an adhesive layer via which one of the two metal coil layers is attached to an external substrate.

8. A wearable haptic feedback device comprising:
a) a substrate; and
b) a bilayer vibrotactile actuator according to claim 1; wherein the bilayer vibrotactile actuator is attached to the substrate.

9. The wearable haptic feedback device according to claim 8, wherein the substrate is a flexible printed circuit board.

10. The wearable haptic feedback device according to claim 8, further comprises an encapsulation that receives the substrate and the bilayer vibrotactile actuator therein.

11. The wearable haptic feedback device according to claim 10, wherein the encapsulation is formed by polydimethylsiloxane.
